(19) United States
(12) Patent Application Publication
(10) Pub. No.: US 2009/0065831 A1
(43) Pub. Date: Mar. 12, 2009

(54) Image Sensor and Method for Manufacturing the Same

(76) Inventor: Byung Ho LEE, Gwangmyeong-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/205,830

(22) Filed: Sep. 5, 2008

(30) Foreign Application Priority Data
Sep. 7, 2007 (KR) 10-2007-0090861

(51) Int. Cl. H01L 31/112; H01L 31/00

(52) U.S. Cl. 257/292; 438/73; 257/E31.079; 257/E31.001

(57) ABSTRACT

Disclosed are an image sensor and a method for manufacturing the same. The image sensor includes a semiconductor substrate including a CMOS circuit, a dielectric layer including a metal interconnection on the semiconductor substrate, a bottom electrode on the metal interconnection, in which the bottom electrode has at least one protrusion, a photodiode on the dielectric layer and the bottom electrode, and a top electrode on the photodiode.

The present application claims priority under 35 U.S.C. 119 to Korean Patent Application No. 10-2007-0090861 (filed on Sep. 7, 2007), which is hereby incorporated by reference in its entirety.

### BACKGROUND

Embodiments of the invention relate to image sensors and methods for manufacturing the same.

An image sensor is a semiconductor device for converting optical images into electric signals, and can be classified into a charge coupled device (CCD) and a CMOS image sensor (CIS). The CMOS sensor includes a photodiode and at least one MOS transistor in each unit pixel, and sequentially detects the electric signals of each unit pixel in a switching mode to realize images.

The CMOS image sensor has a structure in which a photodiode region receives light (e.g., optical signals) and converts the optical signals into electrical signals. The transistor(s) that process the electrical signals are generally disposed on a semiconductor substrate horizontally, relative to the photodiode. When the photodiode is horizontally adjacent to the transistor(s) on the semiconductor substrate in the CMOS image sensor, additional area on the substrate for the photodiode is required.

### SUMMARY

Embodiments of the invention provide an image sensor and a method for manufacturing the same, capable of vertically integrating a transistor-based circuit with a photodiode.

According to one embodiment, an image sensor may include a semiconductor substrate including a CMOS circuit (e.g., transistors for a unit pixel), a dielectric layer on the semiconductor substrate, including one or more metal interconnections therein, a bottom electrode on the dielectric layer and/or the metal interconnection, in which the bottom electrode has at least one protrusion, a photodiode on the dielectric layer and the bottom electrode, and a top electrode on the photodiode.

According to another embodiment, a method for manufacturing an image sensor may include the steps of forming a CMOS circuit on a semiconductor substrate, forming a dielectric layer including a metal interconnection on the semiconductor substrate, forming a bottom electrode on the metal interconnection, in which the bottom electrode has at least one protrusion, forming a photodiode on the dielectric layer and the bottom electrode, and forming a top electrode on the photodiode.

### BRIEF DESCRIPTION OF THE DRAWINGS

FIGS. 1 to 6 are cross-sectional views showing an exemplary method for manufacturing an image sensor according to one embodiment;

FIG. 7 is an enlarged cross-sectional view showing an area A of FIG. 6;

FIG. 8 is a circuit view of a conventional 4Tr type unit pixel including one photodiode and four transistors (a transfer transistor, a reset transistor, a drive transistor, and a select transistor); and

FIG. 9 is a conventional 3Tr unit pixel including one photodiode and three transistors (a reset transistor, a drive transistor, and a select transistor).

### DETAILED DESCRIPTION OF THE EMBODIMENTS

Hereinafter, an exemplary image sensor and an exemplary method for manufacturing the same according to embodiments of the invention will be described with reference to accompanying drawings.

FIG. 6 is a cross-sectional view showing an exemplary image sensor according to various embodiments.

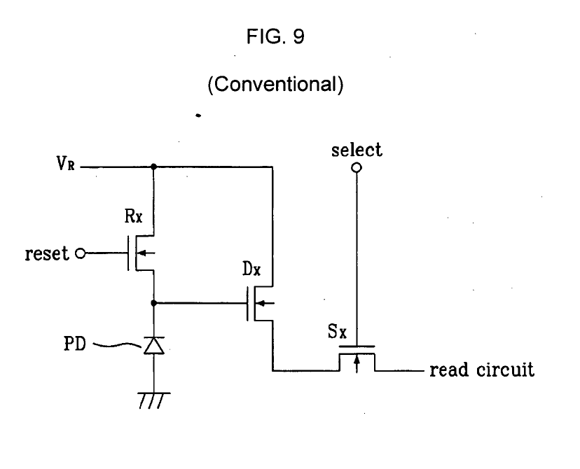

Referring to FIG. 6, a semiconductor substrate 10 and a CMOS circuit 11 are shown. The CMOS circuit 11 is provided corresponding to each pixel, and includes a transfer transistor (Tx 20 in FIG. 8) or a reset transistor (Rx in FIG. 9) connected with a photodiode 80 (see also PD 10 in FIG. 8 and PD in FIG. 9) provided at the upper portion of the semiconductor 10 to convert received optical signals and/or charges into electrical signals. The CMOS circuit (e.g., for each unit pixel) may further comprise a reset transistor (e.g., Rx 30 in FIG. 8), a drive transistor (e.g., Dx 40 in FIG. 8 and Dx in FIG. 9) and a select transistor (e.g., Sx 50 in FIG. 8 and Sx in FIG. 9).

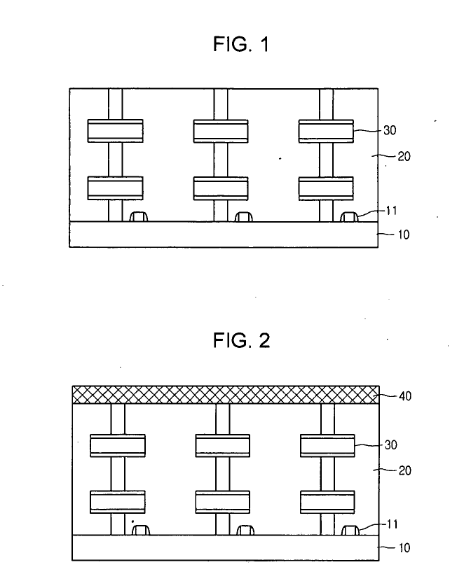

An interlayer dielectric layer 20 including a metal interconnection 30 is provided on the semiconductor substrate 10. A plurality of the interlayer dielectric layers 20 and a plurality of the metal interconnections 30 may be provided, as shown in FIGS. 1 and 6. Each dielectric layer 20 may independently comprise a lowermost etch stop layer (e.g., silicon nitride) one or more conformal and/or gap-fill dielectric layers (e.g., TEOS, plasma silane, or silicon-rich oxide), one or more bulk dielectric layers (e.g., silicon oxycarbide [SiOC], which may be hydrogenated [e.g., SiOCH]; undoped silicon dioxide [e.g., USG or a plasma silane]; or silicon dioxide doped with fluorine [e.g., FSG] or boron and/or phosphorous [e.g., BSG, PSG, or BPSG]), and/or one or more cap layers (e.g., TEOS, USG, plasma silane, etc.). Each metal interconnection 30 may independently comprise one or more lowermost adhesive and/or diffusion barrier layers (e.g., titanium, titanium nitride, tantalum, tantalum nitride, etc., such as a titanium nitride-on-titanium bilayer), a bulk conductive layer (e.g., aluminum, an aluminum alloy [e.g., Al with from 0.5 to 4 wt. % Cu, up to 2 wt. % Ti, and/or up to 1 wt. % Si], or copper), and/or one or more uppermost adhesive, hillock prevention and/or antireflective coating layers (e.g., titanium, titanium nitride, titanium tungsten alloy, etc., such as a titanium nitride-on-titanium bilayer). The lowermost metal interconnection 30 may be electrically connected to a source/drain terminal (e.g., of the transfer or reset transistor) in the substrate 10 by a conventional tungsten plug or via, which may further include an adhesive and/or diffusion barrier layer (e.g., a titanium nitride-on-titanium bilayer) between it and the dielectric layer 20. An overlying metal interconnection 30 may be electrically connected to an underlying metal interconnection (e.g., the lowermost metal interconnection) by such a tungsten plug. Alternatively, metal interconnections 30 and, when the metal interconnection is an overlying metal interconnection 30, the underlying plug or via may comprise a conventional dual damascene copper interconnection (which may further include an adhesive and/or diffusion barrier layer, such as a tantalum nitride-on-tantalum bilayer, and a seed layer such as sputtered copper, ruthenium or other metal, between it and the dielectric layer 20).

A bottom electrode 45 is provided on (e.g., in electrical communication with) the metal interconnection 30. For example, the bottom electrode 45 may include a metal such as chromium (Cr), titanium (Ti), tungsten titanium (TiW) and/or tantalum (Ta). Alternatively, the bottom electrode 45 may (further) comprise molybdenum (Mo), titanium nitride (TiN), tungsten (W), tungsten nitride (WN), or tantalum nitride (TaN). The bottom electrode 45 is provided on the metal interconnection 30 and the interlayer dielectric layer 20 such that the metal interconnection 30 is not exposed. In addition, the bottom electrode 45 is provided on the metal interconnections 30 provided in or corresponding to each pixel, so that the bottom electrodes 45 are spaced apart from each other corresponding to the unit pixels.

The bottom electrode 45 may be formed on the surface thereof with a protrusion 41. Generally, the bottom electrode 45 includes a plurality of such protrusions 41. The protrusion 41 may have one of a triangular shape, a polygonal shape, and a circular shape. Protrusions 41 having an acute shape may result in a potential concentration (e.g., of electrical charges) on the surface of the bottom electrode 45.

A photodiode 80 is provided on the interlayer dielectric layer 20 and/or the bottom electrode 45. The photodiode 80 includes a first conductive-type layer 50, an intrinsic layer 60, and a second conductive-type layer 70. For example, the first conductive-type layer 50 may include n-type amorphous silicon, the intrinsic layer 60 may include intrinsic amorphous silicon, and the second conductive-type layer 70 may include p-type amorphous silicon. Alternatively, the photodiode 80 may include just the intrinsic layer 60 and the second conductive-type layer 70.

A top electrode 90 may be disposed on the upper portion of the photodiode 80. The top electrode 90 may include a transparent electrode having excellent and/or superior light transmittance and excellent and/or superior conductivity. For example, the top electrode 90 may include at least one of ITO (indium tin oxide), CTO (cadmium tin oxide), and ZnOₓ (e.g., ZnO [zinc oxide] or ZnO₂ [zinc peroxide]). The photodiode 80 and the top electrode 90 may also be patterned to form a trench along the boundaries or borders of each unit pixel, and a light-blocking material may be deposited therein to reduce and/or prevent cross-talk between unit pixels.

As described above, the CMOS circuit 11 is vertically integrated with the photodiode 80, so that the fill factor of an image sensor may be improved.

In addition, the protrusion(s) 41 having an acute shape may be formed on the surface of the bottom electrode 45 so that the capacity for receiving electrons generated from the photodiode 80 can be improved. Potential concentration (e.g., of charges) may occur due to the protrusion(s) 41 formed on the surface of the bottom electrode 45, so that electrons of the photodiode 80 can be concentrated on the bottom electrode 45. In addition, concentrating the electrons of the photodiode 80 on a corresponding portion of the bottom electrode 45 can reduce cross-talk and noise between adjacent pixels.

Hereinafter, an exemplary method for manufacturing an image sensor according to various embodiments will be described with reference to FIGS. 1 to 6.

Referring to FIG. 1, the interlayer dielectric layer 20 including the metal interconnection 30 is formed on the semiconductor substrate 10 provided with the CMOS circuit 11. The various layers of the dielectric layer 20 and the metal interconnection 30 can be formed by conventional deposition (e.g., sputtering of metal, which may be performed in an atmosphere containing a conductive compound-forming gas [e.g., nitrogen]; chemical vapor deposition [CVD] of a dielectric or conductive material from an appropriate precursor, which may be plasma assisted, plasma enhanced [PECVD], high-density plasma assisted [HDP-CVD], etc.) and patterning (e.g., depositing and photolithographic patterning a photoresist, followed by [selective] wet or dry etching using the patterned photoresist and/or patterned overlying material as a mask, and removing the patterned photoresist).

The semiconductor substrate 10 may be formed thereon with the CMOS circuit 11 including a transfer transistor connected with the photodiode 80 (e.g., in the example of FIG. 8), as described herein, to convert received light and/or optically-generated charges into electrical signals. The CMOS circuit 11 (e.g., each unit pixel) may (further) comprise a reset transistor, a drive transistor and a select transistor (see, e.g., FIGS. 8-9).

The dielectric layer 20 and the metal interconnection 30 are formed on the semiconductor substrate 10 provided with the CMOS circuit 11 for purposes including connecting with unit pixel to a power line and/or a signal line. For purposes of clarity, the specific metal interconnections 30 that connect the unit pixel to external power and/or signal lines are not shown in the Figures. The specific metal interconnections 30 shown in FIGS. 1-6 may function as pads to electrically connect the contacts/vias between the lower electrode 45 and the CMOS circuitry 11 on the substrate 10. The interlayer dielectric layer 20 may include a plurality of layers, as described above. For example, the interlayer dielectric layer 20 may include an oxide layer.

A plurality of metal interconnections 30 may be provided in the interlayer dielectric layer 20. For example, the metal interconnection 30 may include a metal, an alloy, or various conductive materials (e.g., aluminum, copper, cobalt, or tungsten), including a metal silicide or salicide (e.g., CoSiₓ, TiSiₓ, NiSiₓ, WSiₓ, etc.) . The metal interconnection 30 delivers electrons generated from the photodiode 80 to the CMOS circuit 11 provided at the lower portion of the substrate 10.

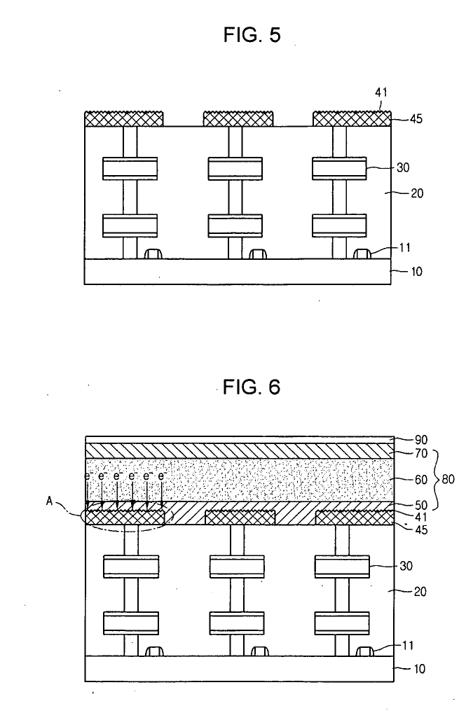

Referring to FIG. 5, the bottom electrode 45 is formed on the interlayer dielectric layer 20, including on the metal interconnection 30. For example, the bottom electrode 45 may include a metal such as chromium (Cr), titanium (Ti), tungsten titanium (TiW) and tantalum (Ta). Alternatively, the bottom electrode 45 may (further) comprise a metal or metal compound such as molybdenum (Mo), titanium nitride (TiN), tungsten (W), tungsten nitride (WN), or tantalum nitride (TaN).

The bottom electrodes 45 are formed on the metal interconnections 30 and aligned corresponding to the pixels. In addition, the protrusion 41 protrudes from the (upper) surface of the bottom electrode 45.

The protrusion(s) 41 formed on the surface of the bottom electrode 45 can receive electrons generated from the photodiode 80 and deliver the electrons to the metal interconnection 30. In other words, when the protrusion 41 formed on the surface of the bottom electrode 45 has an acute shape, potential concentration may occur. The electron-receiving capacity of the bottom electrode 45 may be improved due to potential concentration of the protrusion 41, so that electrons generated in the photodiode 80 can be effectively delivered to the metal interconnection 30. In addition, concentrating the electrons of the photodiode 80 onto the corresponding bottom electrode 45 can reduce or prevent interference (e.g., cross-talk and noise) between adjacent pixels and/or bottom electrodes 45.

A method for forming the bottom electrode 45 will be described with reference to FIGS. 2 to 5.

Referring to FIG. 2, a bottom electrode layer 40 is formed on the interlayer dielectric layer 20 and the metal interconnection 30. For example, the bottom electrode layer 40 may be formed by depositing chromium (Cr) by a PVD (Physical Vapor Deposition) or sputtering process.

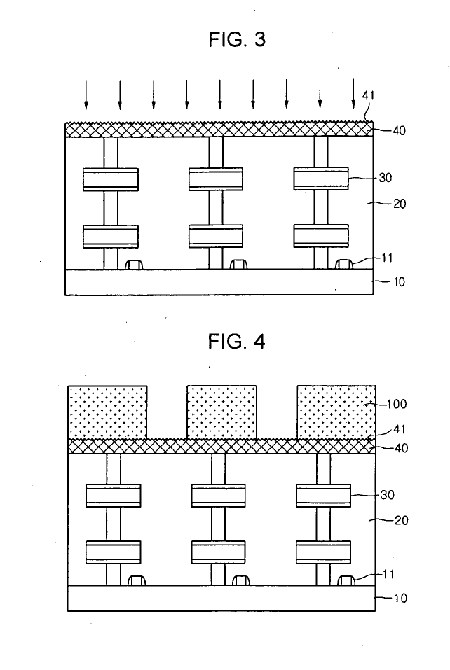

Referring to FIG. 3, the surface of the bottom electrode layer 40 is roughened or etched using at least one of a sputtering process, an etching process, and a reactive ion etching (RIE) process. For example, if the sputtering process or the RIE process is performed with respect to the surface of the bottom electrode layer 40, protrusions 41 having an acute triangular shape may be formed on the surface of the bottom electrode layer 40. In addition, if a wet etching process is performed on the surface of the bottom electrode layer 40, protrusions 41 having a polygonal shape or a circular shape may be formed on the surface of the bottom electrode 40. In various embodiments, the roughened upper surface of the bottom electrode layer 40 has an average surface roughness of at least 10 Å rms (root mean square). For example, the upper surface of the bottom electrode layer 40 may have an average surface roughness of at least 15, 20, 25, 30 or 50 Å rms.

Referring to FIGS. 4 and 5, a photoresist pattern 100 is formed on the bottom electrode layer 40. The pattern covers the bottom electrode layer 40 in areas corresponding to the metal interconnection 30. Then, the bottom electrode layer 40 is etched using the photoresist pattern 100 as an etch mask, so that the bottom electrode 45 having the protrusion(s) 41 is formed on the metal interconnection 30.

Although it is not shown, the bottom electrode 45 may be formed by patterning the bottom electrode layer 40 formed on the interlayer dielectric layer 20. In addition, the surface of the bottom electrode 45 may be etched through at least one of a sputtering process, an etching process, and a reactive ion etching (RIE) process, such that the protrusion(s) 41 is/are formed on the surface of the bottom electrode 45.

Referring to FIG. 6, the photodiode 80 is formed on the interlayer dielectric layer 20 and the bottom electrode 45 such that the photodiode 80 is connected to the metal interconnection 30. Alternatively, the photodiode 80 may be formed on only the bottom electrode 45, for example by depositing the layers of material for the photodiode prior on the lower electrode layer 40 to patterning the lower electrode layer 40.

According to one embodiment, the photodiode 80 includes an NIP diode. The NIP diode has a structure comprising a metal or other conductor, an n-type amorphous silicon layer, an intrinsic amorphous silicon layer, and a p-type amorphous silicon layer. The NIP diode is a photodiode having a structure in which the intrinsic amorphous silicon layer (a substantially pure semiconductor that may be doped with only enough dopant to provide controlled and/or reproducible electrical properties in the intrinsic layer) is between the p-type silicon layer and the metal. The intrinsic amorphous silicon layer serves as a depletion region, so that charges can be more easily created and stored. According to another embodiment, an IP diode is used as the photodiode, and the IP diode may have a P-I-N structure, an N-I-P structure, or an I-P structure.

In particular, according to the embodiment, a photodiode having an N-I-P structure is employed as an example. An n-type amorphous silicon layer, an intrinsic amorphous silicon layer, and the p-type amorphous silicon layer may be more generally referred to as the first conductive-type layer 50, the intrinsic layer 60, and the second conductive-type layer 70.

Hereinafter, the method for forming a photodiode using the NIP diode will be described with reference to FIG. 6.

The first conductive-type layer 50 is formed on the semiconductor substrate 10. If necessary, the following process may be formed without first forming the first conductive-type layer 50. The first conductive-type layer 50 may serve as an N layer of the N-I-P diode according to one embodiment. In other words, the first conductive-type layer 50 may be an N-type conductive layer, including an N-type dopant such as phosphorous (P), arsenic (As) and/or antimony (Sb). However, the embodiment is not limited thereto. For example, the first conductive-type layer 50 may be formed using n-doped amorphous silicon, but the embodiment is not limited thereto. For example, the first conductive-type layer 50 includes amorphous silicon obtained by depositing phosphorous-doped silicon from a mixture of a phosphorous source such as PH₃ or P₂H₆ with a silicon source such as SiH₄ or Si₂H₆ by plasma enhanced chemical vapor deposition (PECVD).

The intrinsic layer 60 is formed on the first conductive-type conductive layer 50. The intrinsic layer 60 may serve as an I layer of an N-I-P diode according to various embodiments. The intrinsic layer 60 may be formed using intrinsic amorphous silicon. For example, the intrinsic layer 60 may be formed by PECVD using a silicon source such as SiH₄ or Si₂H₆. In this case, the intrinsic layer 60 may have a thickness corresponding to about 10 to 1000 times the thickness of the second conductive-type layer 70. This is advantageous to creating and storing a great amount of photocharges because the depletion region of the PIN diode is expanded as the thickness of the intrinsic layer 60 is increased.

The second conductive-type layer 70 is formed on the intrinsic layer 60. The second conductive-type layer 70 may be formed subsequently to the process for forming the intrinsic layer 60. The second conductive-type layer 70 may serve as a P layer of the N-I-P diode according to various embodiments. In other words, the second conductive-type layer 70 may include a P-type conductive layer. However, the embodiment is not limited thereto. For example, the second conductive-type layer 70 may be formed by depositing p-doped amorphous silicon from a mixture of a silicon source such as SiH₄ or Si₂H₆ with a p-dopant such as a BH₃ complex (e.g., BH₃ etherate) or B₂H₆ using PECVD.

The top electrode 90 is formed on the photodiode 80. The top electrode 90 may include a transparent electrode having excellent and/or superior light transmittance and excellent and/or superior conductivity. For example, the top electrode 90 may include one of ITO (indium tin oxide), CTO (cadmium tin oxide), ZnO (zinc oxide) and ZnO₂ (zinc peroxide).

Although it is not shown, a color filter and a micro-lens may be additionally formed on the top electrode 90 corresponding to each unit pixel.

The photodiode 80, which includes the first conductive-type layer 50, the intrinsic layer 60, and the second conducive-type layer 70 as described above, is vertically integrated with the CMOS circuit 11, so that the fill factor of the photodiode 80 can approach or reach approximately 100%.

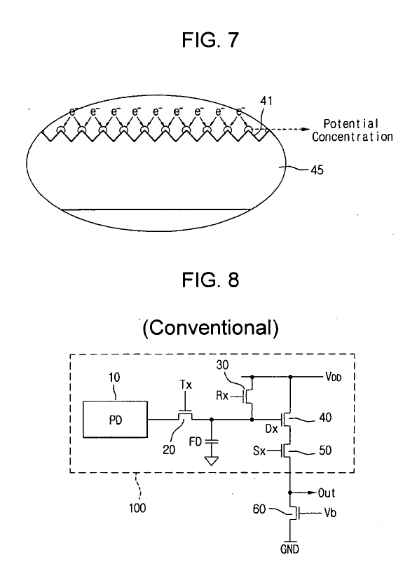

Referring to FIG. 7, a plurality of the protrusions 41 having an acute shape may be formed on the bottom electrode 45, so that electrons generated from the photodiode 80 are concentrated onto the bottom electrode 45. Accordingly, the electrons can be effectively delivered to the CMOS circuit.

In addition, the electron-receiving capacity of the bottom electrode 45 can be improved due to potential concentration derived from the shape of the bottom electrode 45. In addition, when the bottom electrode 45 has a shape facilitating potential concentration of electrical charges generated in the photodiode 80, interference (e.g., cross-talk and/or noise) between adjacent bottom electrodes can be reduced or prevented.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate including a CMOS circuit;
a dielectric layer including a metal interconnection on the semiconductor substrate;
a bottom electrode on a surface of the metal interconnection, the bottom electrode having at least one protrusion;
a photodiode on the dielectric layer and the bottom electrode; and
a top electrode on the photodiode.

2. The image sensor of claim 1, wherein the protrusion has at least one of a triangular shape, a polygonal shape, and a circular shape.

3. The image sensor of claim 1, wherein the bottom electrode includes at least one of chromium (Cr), titanium (Ti), tungsten titanium (TiW) and tantalum (Ta).

4. A method for manufacturing an image sensor, the method comprising the steps of:
forming a CMOS circuit on a semiconductor substrate;
forming a dielectric layer including a metal interconnection on the semiconductor substrate;
forming a bottom electrode on the metal interconnection, the bottom electrode having at least one protrusion;
forming a photodiode on the dielectric layer and the bottom electrode; and
forming a top electrode on the photodiode.

5. The method of claim 4, wherein forming the bottom electrode includes:
forming a bottom electrode layer on the dielectric layer;
forming the protrusion by performing a sputtering process or an etching process on a surface of the bottom electrode layer; and
patterning the bottom electrode layer in a manner corresponding to the metal interconnection.

6. The method of claim 4, wherein forming the bottom electrode includes:
forming a bottom electrode layer on the interlayer dielectric layer;
forming the bottom electrode on the metal interconnection by patterning the bottom electrode layer; and
forming the protrusion by sputtering or etching a surface of the bottom electrode.

7. The method of claim 4, wherein the bottom electrode includes at least one of chromium (Cr), titanium (Ti), tungsten titanium (TiW) and tantalum (Ta).

8. The method of claim 4, wherein the protrusion has an acute triangular shape and is formed by a dry etching process.

9. The method of claim 4, wherein the protrusion has a polygonal shape or a circular shape and is formed by a wet etching process.

10. A unit pixel for a CMOS image sensor, comprising:
a semiconductor substrate including a plurality of MOS transistors;
a dielectric layer on the semiconductor substrate;
one or more metal interconnections in the dielectric layer;
a bottom electrode on a surface of the dielectric layer and in electrical communication with the at least one metal interconnection, the bottom electrode having an upper surface with a plurality of protrusions thereon; and
a photodiode on the bottom electrode.
a top electrode on the photodiode.

11. The unit pixel of claim 10, wherein the upper surface of the bottom electrode has an average surface roughness of at least 10 Å rms (root mean square).

12. The unit pixel of claim 10, wherein the bottom electrode comprises a material selected from the group consisting of chromium (Cr), molybdenum (Mo), titanium (Ti), titanium nitride (TiN), titanium tungsten (TiW), tungsten (W), tungsten nitride (WN), tantalum (Ta) and tantalum nitride (TaN).

13. The unit pixel of claim 10, wherein the plurality of MOS transistors comprises a select transistor, a drive transistor, and a reset transistor.

14. The unit pixel of claim 13, wherein the plurality of MOS transistors further comprises a transfer transistor.

15. A method for manufacturing an image sensor, the method comprising the steps of:
forming a plurality of transistors on a semiconductor substrate;
forming a dielectric layer on the semiconductor substrate;
forming a metal interconnection on and/or in the dielectric layer;
forming a bottom electrode on the metal interconnection, the bottom electrode having an upper surface with a plurality of protrusions; and
forming a photodiode on the bottom electrode.

16. The method of claim 15, wherein forming the bottom electrode includes:
forming a bottom electrode layer on the dielectric layer; and
patterning the bottom electrode layer to form the bottom electrode electrically connected to the metal interconnection.

17. The method of claim 16, wherein forming the plurality of protrusions comprises sputtering or etching the surface of the bottom electrode or the bottom electrode layer.

18. The method of claim 17, wherein forming the plurality of protrusions comprises a dry etching process.

19. The method of claim 17, wherein forming the plurality of protrusions comprises a wet etching process.

20. The method of claim 15, wherein the bottom electrode comprises a material selected from the group consisting of chromium (Cr), molybdenum (Mo), titanium (Ti), titanium nitride (TiN), titanium tungsten (TiW), tungsten (W), tungsten nitride (WN), tantalum (Ta) and tantalum nitride (TaN).
